(19) United States
(12) Patent Application Publication
(10) Pub. No.: US 2026/0221727 A1
(43) Pub. Date: Jul. 30, 2026

(54) BURIED TYPE OPTICAL SEMICONDUCTOR DEVICE

(71) Applicant: Lumentum Operations LLC, San Jose, CA (US)

(72) Inventors: Takeo KAGEYAMA, Yokohama (JP); Shigenori HAYAKAWA, Hadano (JP)

(21) Appl. No.: 19/249,030

(22) Filed: Jun. 25, 2025

(30) Foreign Application Priority Data
Jan. 29, 2025 (JP) 2025012782
Mar. 7, 2025 (JP) 2025036481

(51) Int. Cl. H01S 5/227; H01S 5/323

(52) U.S. Cl. CPC H01S 5/227; H01S 5/323

(57) ABSTRACT

The buried layer includes, from the semiconductor substrate side, a first buried layer, a second buried layer, and a third buried layer in the stated order, the third buried layer being formed of a material different from a material of the second buried layer. The second buried layer has a distal end on the mesa structure side. At the distal end, a lower surface of the second buried layer is arranged on the semiconductor substrate side with respect to an upper surface of the contact layer. The electrode is in contact with the contact layer and the second buried layer.

### CROSS-REFERENCE TO RELATED APPLICATION

This Patent Application claims priority to Japan Patent Application No. JP 2025-036481, filed on March 7, 2025, and Japan Patent Application No. JP 2025-012782, filed on January 29, 2025. The disclosures of the prior Applications are considered part of and are incorporated by reference into this Patent Application.

### TECHNICAL FIELD

The present disclosure relates generally to a buried type optical semiconductor device.

### BACKGROUND

An optical semiconductor device can be used in various applications such as optical communication, information processing, as a light source, and the like, and is often demanded to be provided with low cost, low power consumption, small size, high optical output, and high reliability. In general, an optical semiconductor device includes a semiconductor crystal forming a pn junction, and a metal forming an electrode. In an optical semiconductor device including a buried-heterostructure (BH), the semiconductor crystal including the pn junction is formed as a mesa structure, and a side portion of the mesa structure is buried with a buried layer of a semi-insulating semiconductor or the like. Accordingly, in this optical semiconductor device, the electrode is arranged across an upper surface of the mesa structure (a surface at which an upper portion of a contact layer is exposed) and an upper surface of the buried layer.

The metal forming the electrode of the optical semiconductor device is generally deposited on a semiconductor crystal layer by a high-temperature process, such as electron beam evaporation. When the temperature of the deposited metal is reduced from a high temperature to room temperature, a stress is generated in the semiconductor crystal layer due to a difference in thermal expansion coefficients between the semiconductor and the metal. Such a stress is known to adversely affect a performance of the optical semiconductor device.

In some cases, there is a structure for reducing, in an optical semiconductor device in which an upper portion of a mesa structure protrudes from a surface of a buried layer, a stress to be received from an electrode layer by a side surface of the upper portion of the mesa structure.

In some other cases, the stress is reduced by separating a part of an electrode between the upper surface of the mesa structure and the side surface of the upper portion of the mesa structure. However, in a process of causing the upper portion of the mesa structure to protrude from the surface of the buried layer, in some cases, manufacturing variations may occur, and the upper portion of the mesa structure may protrude in an amount larger than expected. That is, in some cases, a step difference between the upper surface of the mesa structure and the surface of the buried layer adjacent to the mesa structure may be increased. When the protruding amount of the mesa structure is large, the area of the electrode formed on the side surface of the upper portion of the mesa structure is increased, and a strong stress is applied by the metal electrode to both side surfaces of the mesa structure. There is a concern that this stress adversely affects an optical characteristic such as a side mode suppression ratio (SMSR).

Some implementations described herein include a buried type optical semiconductor device which is excellent in optical characteristic, and with which a stress to be applied to an upper portion of a mesa structure due to a metal electrode can be reduced.

### SUMMARY

According to at least one implementation of the present invention, a buried type optical semiconductor device includes: a semiconductor substrate; a mesa structure provided on the semiconductor substrate, the mesa structure including a contact layer and extending in an extending direction; a buried layer provided so as to cover a side surface of the mesa structure; and an electrode configured to supply a current to the mesa structure. The buried layer includes, from the semiconductor substrate side, a first buried layer, a second buried layer, and a third buried layer in the stated order, the third buried layer being formed of a material different from a material of the second buried layer. The second buried layer has a distal end on the mesa structure side. At the distal end, a lower surface of the second buried layer is arranged on the semiconductor substrate side with respect to an upper surface of the contact layer. The electrode is in contact with the contact layer and the second buried layer.

### BRIEF DESCRIPTION OF THE DRAWINGS

FIG. 1 is an example of a top view of a buried type optical semiconductor device according to a first example implementation of the present invention.

FIG. 2 is a schematic sectional view taken along the line II-II of the buried type optical semiconductor device illustrated in FIG. 1.

FIG. 3 is a view for illustrating a step of manufacturing the buried type optical semiconductor device illustrated in FIG. 1.

FIG. 4 is a view for illustrating a step of manufacturing the buried type optical semiconductor device illustrated in FIG. 1.

FIG. 5 is a schematic sectional view taken along the line II-II in a modification example of the buried type optical semiconductor device illustrated in FIG. 1.

FIG. 6 is an example of a top view of a buried type optical semiconductor device according to a second example implementation of the present invention.

FIG. 7 is a schematic sectional view taken along the line VII-VII of the buried type optical semiconductor device illustrated in FIG. 6.

FIG. 8 is a schematic sectional view taken along the line VIII-VIII of the buried type optical semiconductor device illustrated in FIG. 6.

FIG. 9 is a schematic sectional view taken along the line IX-IX of the buried type optical semiconductor device illustrated in FIG. 6.

FIG. 10 is an example of a top view of a buried type optical semiconductor device according to a third example implementation of the present invention.

FIG. 11 is a schematic sectional view taken along the line XI-XI of the buried type optical semiconductor device illustrated in FIG. 10.

### DETAILED DESCRIPTION

The following detailed description of example implementations refers to the accompanying drawings. The same reference numbers in different drawings may identify the same or similar elements. Elements may not be drawn to scale.

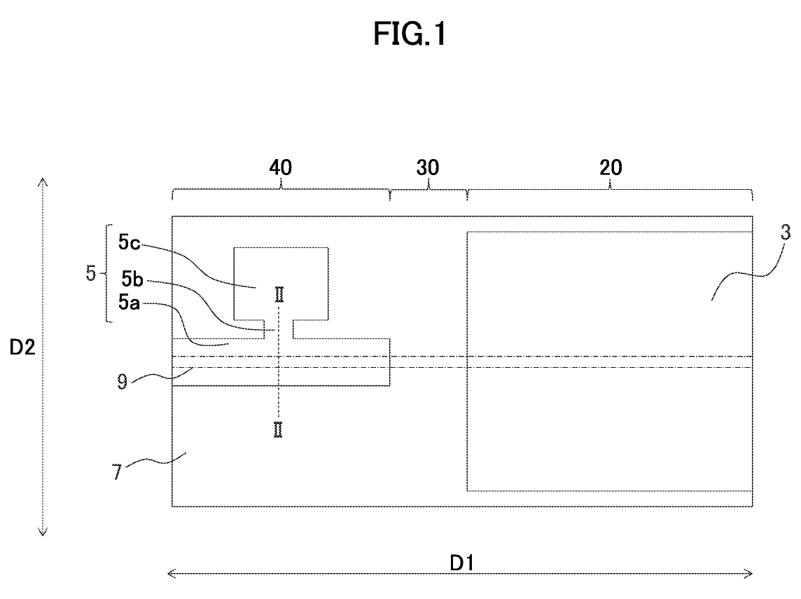

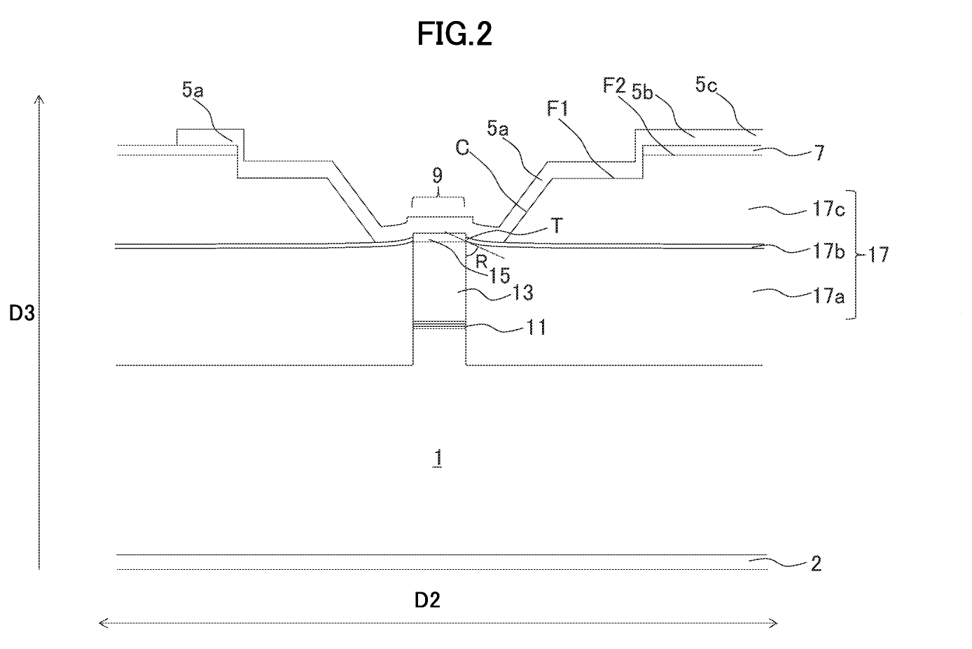

FIG. 1 is a top view of a buried type optical semiconductor device according to a first example implementation of the present invention. FIG. 2 is a schematic sectional view taken along the line II-II of FIG. 1. The buried type optical semiconductor device includes three optical function devices integrated on a substrate 1. The three optical function devices are a semiconductor laser portion 20, a connecting waveguide portion 30, and a modulator portion 40. The modulator portion 40 here is an electro-absorption modulator, but is not limited thereto. The substrate 1 is a semiconductor substrate of a first conductivity type, and is an n-type InP substrate here. The buried type optical semiconductor device has a back surface electrode 2 on a back surface of the substrate 1, a laser electrode 3 on a front side of the semiconductor laser portion 20, and a modulator electrode 5 on a front side of the modulator portion 40. The back surface electrode 2, the laser electrode 3, and the modulator electrode 5 may be metal layers. A current may be injected between the laser electrode 3 and the back surface electrode 2 so that the semiconductor laser portion 20 oscillates and emits continuous light. The continuous light emitted by oscillation may be input to the connecting waveguide portion 30 and may be propagated to the modulator portion 40. An electric signal having a high frequency may be applied between the modulator electrode 5 and the back surface electrode 2, and the continuous light may be converted into a high-frequency optical signal having a frequency that varies depending on the applied electric signal. The high-frequency optical signal exits from a facet on the modulator portion 40 side. An insulating film 7 may be formed on a front surface of the buried type optical semiconductor device. The back surface electrode 2 may be provided for each light function device separately. Although not shown, a low-reflection facet coating film may be formed on the facet on the modulator portion 40 side. A high-reflection facet coating film may be formed on a facet on the semiconductor laser portion 20 side. However, a low-reflection facet coating film may be formed also on the facet on the semiconductor laser portion 20 side in place of the high-reflection facet coating film.

The buried type optical semiconductor device may include a mesa structure 9. The mesa structure 9 extends in an extending direction D1, and may be arranged across the semiconductor laser portion 20, the connecting waveguide portion 30, and the modulator portion 40. In the modulator portion 40, the mesa structure 9 may have a structure in which a part of the substrate 1, an absorption layer 11, a second conductivity type cladding layer 13, and a contact layer 15 of a second conductivity type are grown in the stated order from below (from the substrate 1 side). The mesa structure 9 may include other layers. The absorption layer 11 has, for example, a multiple quantum well (MQW) structure. The second conductivity type here may be the “p” type. The substrate 1 may be of the “p” type, and the second conductivity type cladding layer 13 may be of the “n” type. The contact layer 15 comprises a material different from that of the second conductivity type cladding layer 13. Further, an impurity concentration of the contact layer 15 may be higher than an impurity concentration of the second conductivity type cladding layer 13. The contact layer 15 may be formed of a plurality of layers. The contact layer 15 here is a layer formed of a material different from that of the second conductivity type cladding layer 13, and may be an uppermost layer of the mesa structure 9. For example, the second conductivity type cladding layer 13 may be formed of p-InP, and the contact layer 15 may be formed of p-InGaAs. Those materials are merely examples, and the materials are not limited thereto.

The mesa structure 9 in the semiconductor laser portion 20 may have the same structure as that of the mesa structure 9 in the modulator portion 40 except that an active layer (optical function layer) is included in place of the absorption layer 11. That is, the second conductivity type cladding layer 13 and the contact layer 15 in the semiconductor laser portion 20 are the same layers as the second conductivity type cladding layer 13 and the contact layer 15 in the modulator portion 40. However, those layers may be different layers. Further, the mesa structure in the connecting waveguide portion 30 also may have the same structure as that of the mesa structure 9 in the modulator portion 40 except that a waveguide layer is included in place of the absorption layer 11.

The buried type optical semiconductor device includes a buried layer 17. The buried layer 17 may be arranged on both side surfaces of the mesa structure 9. In FIG. 1, an interface between an upper surface of the mesa structure 9 and the buried layer 17 is indicated by the long dashed short dashed line. The buried layer 17 may include a first buried layer 17a, a second buried layer 17b, and a third buried layer 17c. The first buried layer 17a is a semi-insulating semiconductor layer, and may be formed of, for example, InP doped with Fe or Ru. The first buried layer 17a may be grown on the front surface of the substrate 1.

The buried layer 17 may include the second buried layer 17b which may be grown on an upper surface of the first buried layer 17a and may be formed of a material different from that of the first buried layer 17a. The second buried layer 17b is, for example, a layer formed of any one of InGaAs, InAlAs, InGaAlAs, InGaAsP, or InAlAsP. The second buried layer 17b may be a layer obtained by combining a plurality of semiconductor layers formed of those materials.

The buried layer 17 may include the third buried layer 17c grown on an upper surface of the second buried layer 17b. The third buried layer 17c may be a semi-insulating semiconductor layer, and may be formed of, for example, InP doped with Fe or Ru. The first buried layer 17a and the third buried layer 17c may be formed of the same material, or may be formed of materials different from each other. An upper surface of the third buried layer 17c may include a third inclined portion C which may be inclined so as to separate from the substrate 1 as the third inclined portion C separates from the mesa structure 9 in a width direction D2 of the mesa structure 9. The upper surface of the third buried layer 17c may include a first flat portion F1 which may be continuous with the third inclined portion C and extends substantially in parallel with the substrate 1, and a second flat portion F2 which extends substantially in parallel with the substrate 1. There may be a step difference between the first flat portion F1 and the second flat portion F2, but the first flat portion F1 and the second flat portion F2 may be continuous to form a flat surface without a step difference. The third buried layer 17c may be arranged so as to be spaced apart from the mesa structure 9 in the width direction D2.

The second buried layer 17b may be in contact with the contact layer 15 of the mesa structure 9. The second buried layer 17b may include an inclined portion which may be inclined so as to approach the substrate 1 as the inclined portion separates from the mesa structure 9 in the width direction D2, and a flat portion which may be continuous with the inclined portion and may be substantially parallel with the substrate 1. The direction of the inclination of the inclined portion of the second buried layer 17b may be a direction to approach the substrate 1 as illustrated in FIG. 2, or may be an opposite direction (direction to approach the modulator electrode 5). Further, the second buried layer 17b may include an inclined portion inclined in a plurality of directions.

The buried type optical semiconductor device may include the modulator electrode 5 in the modulator portion 40. The modulator electrode 5 may include a mesa electrode 5a which may be grown on the upper surface of the mesa structure 9 and extends in the extending direction D1. The modulator electrode 5 may include a pad electrode 5c which may be grown above the upper surface of the third buried layer 17c. Further, the modulator electrode 5 may include a connection electrode 5b which may be arranged between the mesa electrode 5a and the pad electrode 5c and may be grown on the upper surface of the third buried layer 17c. The mesa electrode 5a may be arranged on, in the width direction D2, a part of a side surface of the contact layer 15, an upper surface of the contact layer 15, the upper surface of the second buried layer 17b, and the third inclined portion C, the first flat portion F1, and a part of the second flat portion F2 of the buried layer 17. In other words, an end portion of the mesa electrode 5a may be arranged above the third buried layer 17c. The connection electrode 5b and the pad electrode 5c may be arranged above the second flat portion F2. The modulator electrode 5 may be a metal layer, and may be a single layer or a plurality of layers.

Etching a buried layer after forming the buried layer causes a whole or a part of a contact layer included in a mesa structure to protrude from the buried layer. That is, a step difference is generated between an upper surface of the mesa structure and the buried layer in the vicinity of the upper portion of the mesa structure. At this time, in some cases, the buried layer may be etched more than expected to generate a large step difference between the mesa structure and the buried layer. When this step difference is large, a metal electrode is formed in a wider area on the side surface of the upper portion of the mesa structure. Thus, a stress is applied to the mesa structure, and an optical characteristic is reduced.

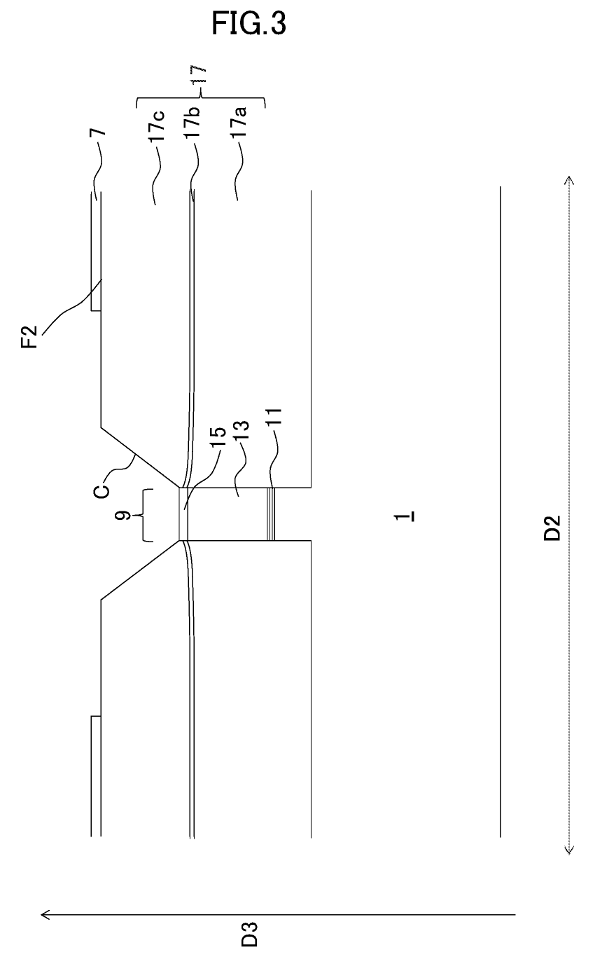

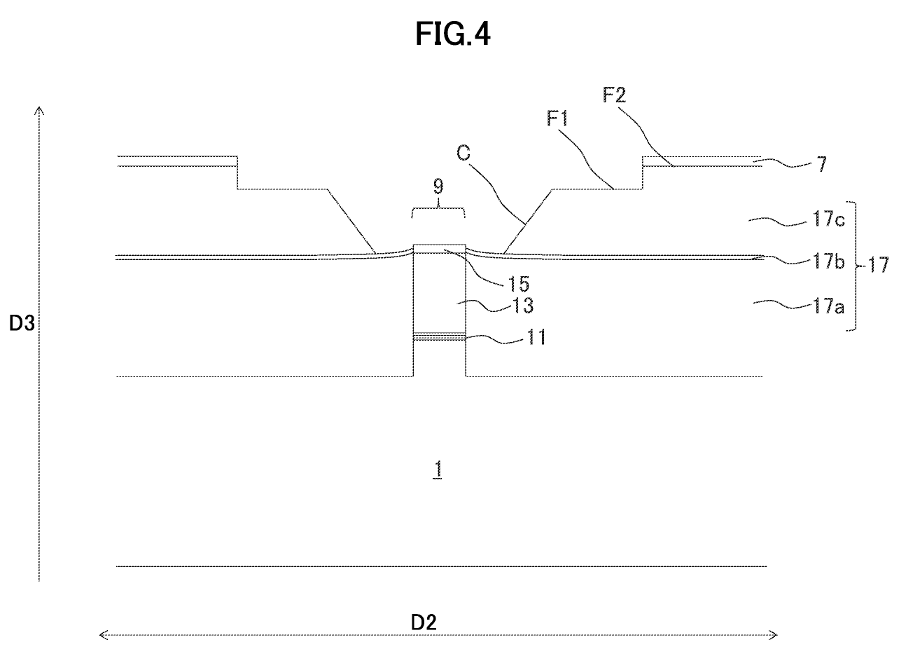

In the buried type optical semiconductor device according to the first example implementation, the second buried layer 17b is arranged to suppress occurrence of variations of the step difference in the above-mentioned etching step. FIG. 3 and FIG. 4 are explanatory schematic views for illustrating the step of etching the buried layer 17. FIG. 3 shows a state after the insulating film 7 is formed on the upper surface of the buried layer 17. Under this state, the third inclined portion C of the buried layer 17 (third buried layer 17c) is formed from the vicinity of the upper surface of the mesa structure 9 serving as a starting point. The surface of the buried layer 17 (third buried layer 17c) is flat, but is not limited thereto. The surface of the buried layer 17 (third buried layer 17c) may have a protruding structure of a so-called rabbit ear. The insulating film 7 here is arranged on the second flat portion F2.

Next, the buried layer 17 may be etched through use of the insulating film 7 as a mask. A chemical solution that provides a sufficient difference in etching rate between the third buried layer 17c and the second buried layer 17b is selected as an etchant. A chemical solution that allows the third buried layer 17c to be etched faster may be selected here. A state after the etching is illustrated in FIG. 4. As is clear from FIG. 4, the third buried layer 17c is etched, the third inclined portion C is separated from the mesa structure 9, and the first flat portion F1 is formed. Meanwhile, the second flat portion F2 masked with the insulating film 7 is not etched. Accordingly, a step difference is generated between the first flat portion F1 and the second flat portion F2. When the second buried layer 17b is not arranged, a step difference equivalent to or larger than the step difference between the first flat portion F1 and the second flat portion F2 may be generated between the upper surface of the mesa structure 9 and the surface of the buried layer 17 in the vicinity of the upper portion of the mesa structure 9. However, in the buried type optical semiconductor device according to the first example implementation, the second buried layer 17b is arranged, and hence the etching stops at the second buried layer 17b. As a result, a step difference between the upper surface of the mesa structure 9 and the surface of the buried layer 17 can be formed stably to a target height. This manufacturing method is merely an example, and the etching may be performed by other procedures.

The modulator electrode 5 and the back surface electrode 2 are formed in the subsequent steps so that a structure having a cross section illustrated in FIG. 2 is obtained. The mesa electrode 5a of the modulator electrode 5 is in contact with both of the upper surface of the mesa structure 9 and the second buried layer 17b in the vicinity of the upper surface of the mesa structure, and a region of the mesa electrode 5a formed on the side surface of the mesa structure 9 is small because a step difference between the upper surface of the mesa structure 9 and the surface of the buried layer 17 is small. As a result, a strong stress is not applied by the metal electrode to the side surface of the upper portion of the mesa structure 9, and a buried type optical semiconductor device which is excellent in optical characteristic such as the SMSR is achieved.

The present invention is not always applied only to the structure in which the step difference is formed in the vicinity of the upper portion of the mesa structure 9. For example, the second buried layer 17b may be arranged so as to prevent an unintended step difference from being generated at the time of etching other regions. Further, the second buried layer 17b also functions as an anti-diffusion layer for gold (Au). In some cases, a metal forming the modulator electrode 5 contains Au. Au has a property of being diffused in InP forming the first buried layer 17a. Meanwhile, a diffusion constant of Au of the material forming the second buried layer 17b listed above may be smaller than a diffusion constant of Au of InP. In general, the modulator electrode 5 may include a metal layer (such as Pt) for preventing Au diffusion between Au and a semiconductor layer (in the first example implementation, the buried layer 17) that becomes a base for growing the modulator electrode 5, but, in some cases, the metal layer may be formed thin due to manufacturing variations and the like, and thus Au may be diffused in the buried layer 17. When Au included in the modulator electrode 5 is diffused to reach the absorption layer 11 via the buried layer 17, there may be concern of reduction in characteristic and reliability. In the first example implementation, the second buried layer 17b is arranged between the modulator electrode 5 and the first buried layer 17a formed of InP, and hence Au can be prevented from being diffused to reach the absorption layer 11. As described above, with the second buried layer 17b being provided, not only the effect of reducing the step difference variations but also other effects can be obtained.

The second buried layer 17b may be desired to be in contact with the mesa structure 9, but the second buried layer 17b is not required to be in contact with the mesa structure 9. In some cases, the first buried layer 17a is arranged between the side surface of the mesa structure 9 and the second buried layer 17b. When a distal end T of the second buried layer 17b on the mesa structure 9 side is excessively separated from the mesa structure 9, a part between the mesa structure 9 and the distal end T may be etched to cause occurrence of an unintended step difference or dent. Accordingly, it may be desired that, in the width direction D2, an interval between the distal end T of the second buried layer 17b and the side surface of the mesa structure 9 be 0.5 μm or less.

It may be desired that, in a height direction D3 of the mesa structure 9, a lower surface (surface on the substrate 1 side) of the second buried layer 17b at the distal end T be arranged on the substrate 1 side with respect to the upper surface of the contact layer 15. Further, it may be desired that, at the distal end T, the upper surface of the second buried layer 17b be arranged to be higher than a lower surface of the contact layer 15. Moreover, it may be more desired that, at the distal end T, the upper surface of the second buried layer 17b be arranged to be higher than the lower surface of the contact layer 15 and equal to or lower than the upper surface of the contact layer 15. It may be further more desired that, at the distal end T, the upper surface of the second buried layer 17b be arranged at the same position as the upper surface of the contact layer 15.

When an angle (inclination angle) R formed between the inclined portion of the second buried layer 17b and the side surface of the mesa structure 9, which is illustrated in FIG. 2, is too steep, there is a possibility that a stress is applied to the mesa structure 9 via the buried layer 17 as a result. Thus, it may be preferred that the inclination angle R be 30 degrees or more. It may be more preferred that the inclination angle R be 60 degrees or more.

The second buried layer 17b may may have any thickness in the height direction D3, but the thickness may be desired to be 5 nm or more, more preferably 10 nm or more, because there may be a fear that the second buried layer 17b does not function as an etching stop layer or a Au anti-diffusion layer when the second buried layer 17b may be too thin. Meanwhile, when the second buried layer 17b may be too thick in the height direction D3, there may be a possibility that light absorption and light distribution may be affected. In order to avoid those effects, it may be desired that the thickness of the second buried layer 17b in the height direction D3 be equal to or smaller than the thickness of the contact layer 15 in the height direction D3. The thickness of the second buried layer 17b in the height direction D3 may be defined as the thickness of the flat portion of the second buried layer 17b. Further, the second buried layer 17b may be formed of any one of an undoped semiconductor, a semi-insulating semiconductor, or a conductive semiconductor.

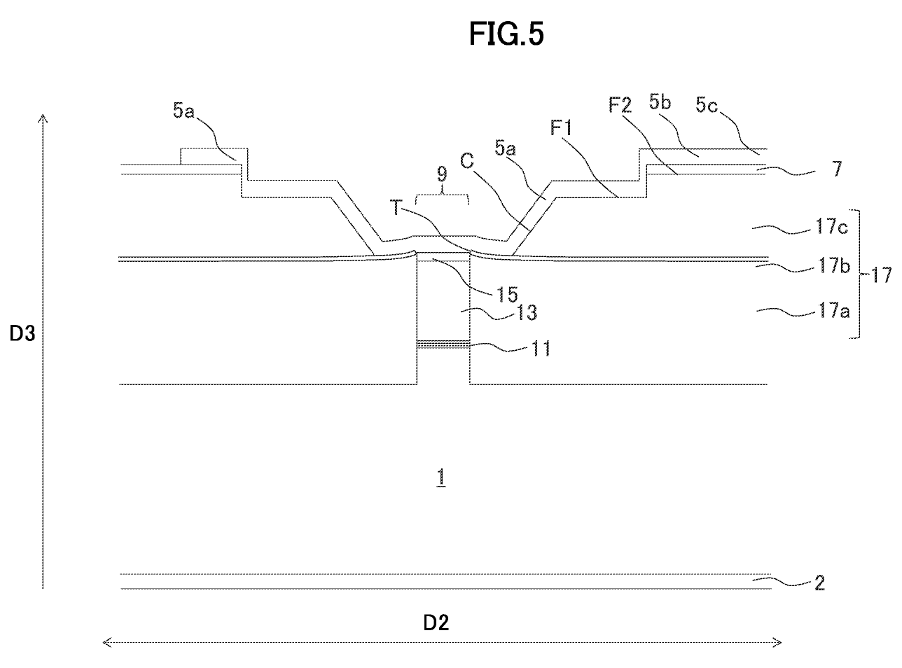

FIG. 5 is a sectional view corresponding to FIG. 2 in a modification example of the buried type optical semiconductor device according to the first example implementation. The difference from the first example implementation resides in that, at the distal end T, the upper surface of the second buried layer 17b is arranged to be higher than the mesa structure 9. Strictly speaking, in the height direction D3, the upper surface of the second buried layer 17b at the distal end T is arranged to be higher than the upper surface of the contact layer 15, but the lower surface of the second buried layer 17b is arranged to be lower than the upper surface of the contact layer 15.

Also in this structure, the effects described above are obtained. For example, when the entire distal end T (the upper surface and the lower surface of the second buried layer 17b at the distal end T) is completely arranged to be higher than the upper surface of the contact layer 15, an inclined part may be formed in the first buried layer 17a, and the distal end T of the second buried layer 17b may be separated from the mesa structure 9 along the inclined part of the first buried layer 17a. As a result, a part between the mesa structure 9 and the distal end T (a portion of the inclined part of the first buried layer 17a) is etched at the time of etching, and a step difference is generated between the upper surface of the mesa structure 9 and the upper surface of the buried layer 17 (surface of the first buried layer 17a) at the upper portion of the mesa structure 9. Accordingly, at the distal end T, even when the upper surface of the second buried layer 17b is arranged to be higher than the upper surface of the mesa structure 9 (upper surface of the contact layer 15), it may be desired that the lower surface of the second buried layer 17b at the distal end T be arranged on the substrate 1 side with respect to the upper surface of the contact layer 15.

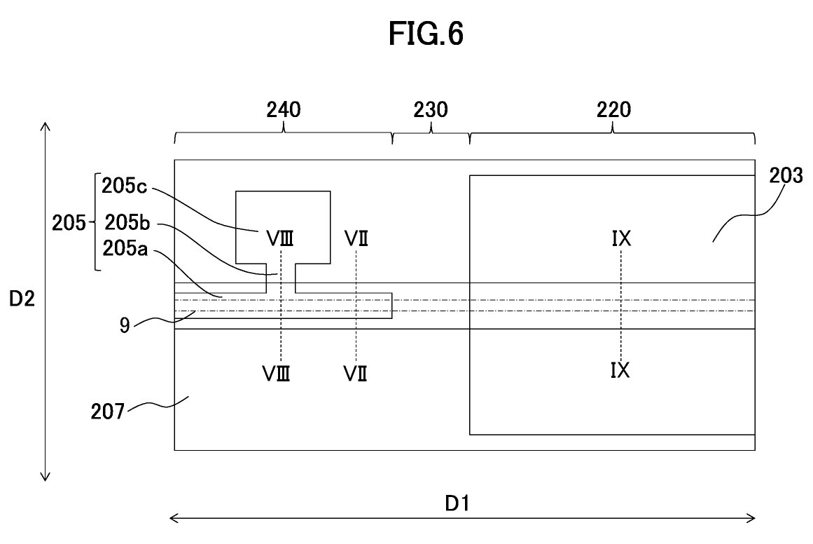

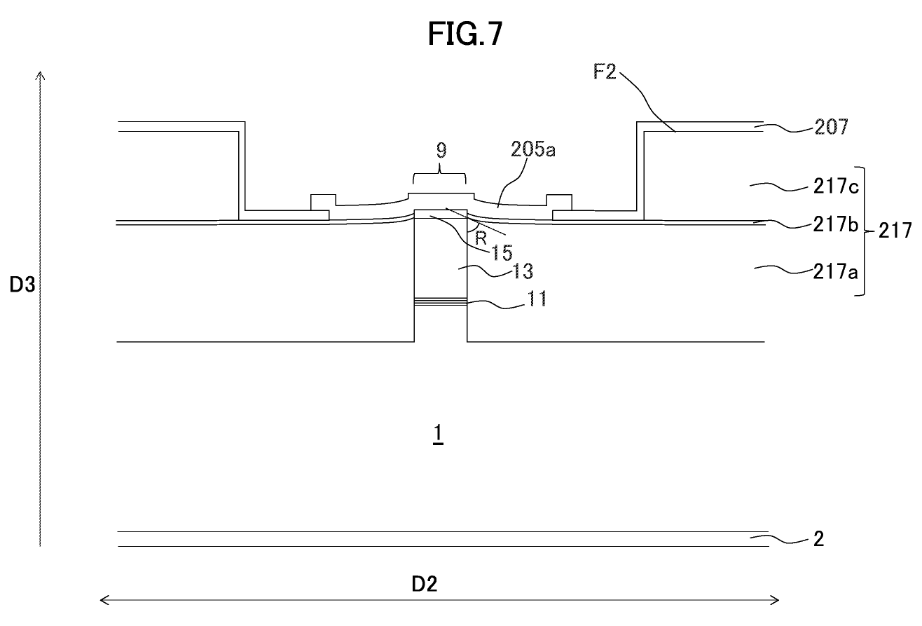

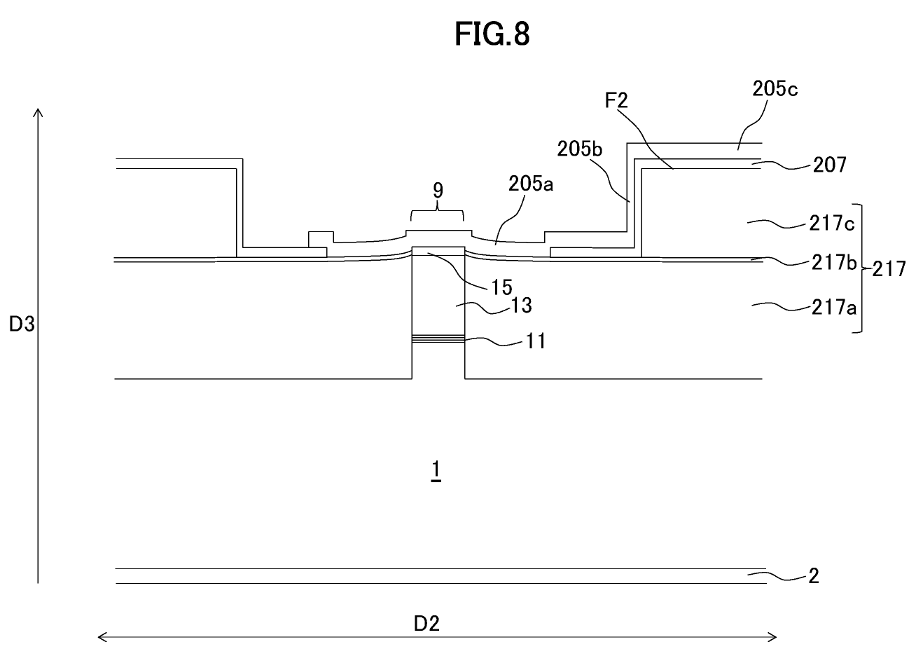

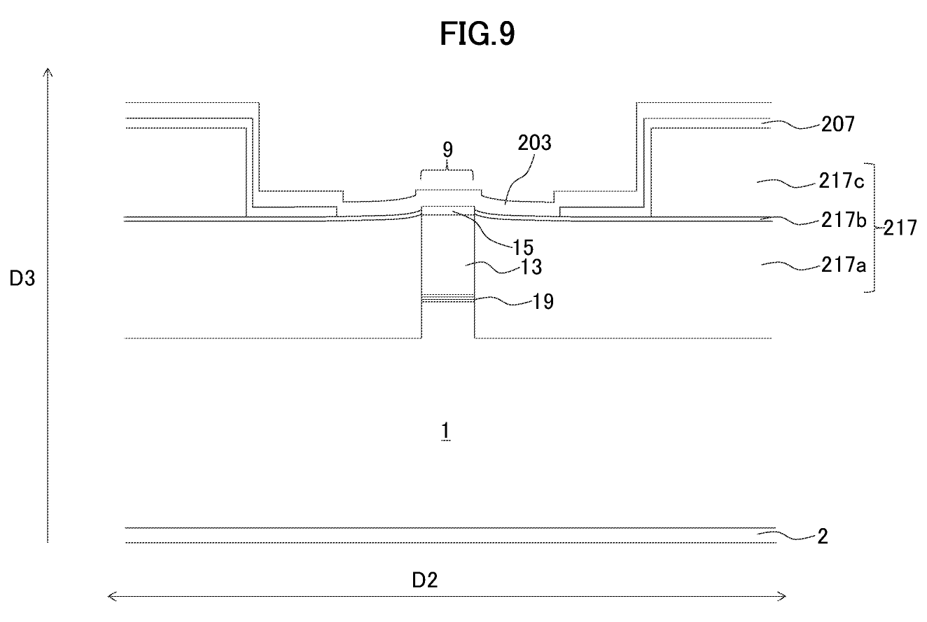

FIG. 6 is a top view of a buried type optical semiconductor device according to a second example implementation of the present invention. FIG. 7 is a schematic sectional view taken along the line VII-VII of FIG. 6. FIG. 8 is a schematic sectional view taken along the line VIII-VIII of FIG. 6. FIG. 9 is a schematic sectional view taken along the line IX-IX of FIG. 6. The buried type optical semiconductor device according to the second example implementation includes three optical function devices integrated on the substrate 1. The three optical function devices are a semiconductor laser portion 220, a connecting waveguide portion 230, and a modulator portion 240. The buried type optical semiconductor device according to the second example implementation includes the mesa structure 9 and a buried layer 217 arranged on both sides of the mesa structure 9 similarly to the first example implementation. The difference from the first example implementation resides in a shape of a third buried layer 217c, a shape of a modulator electrode 205, and the like.

The third buried layer 217c includes no third inclined portion and no first flat portion unlike the first example implementation. In the second example implementation, in the manufacturing steps illustrated in FIG. 3 and FIG. 4, a second buried layer 217b is more widely exposed by increasing the etching time as compared with the first example implementation.

The modulator electrode 205 includes a mesa electrode 205a which may be in contact with the upper surface of the mesa structure 9 and extends in the extending direction D1. The modulator electrode 205 may include a pad electrode 205c arranged above the third buried layer 217c. Further, the modulator electrode 205 may include a connection electrode 205b arranged between the mesa electrode 205a and the pad electrode 205c. The mesa electrode 205a may be arranged only on, in the width direction D2, parts of the side surfaces of the contact layer 15, the upper surface of the contact layer 15, and the upper surface of the second buried layer 17b. In other words, the end portion of the mesa electrode 205a in the width direction D2 may be arranged on the second buried layer 217b, but may not be arranged on the third buried layer 217c. Further, in the width direction D2, the width of the mesa electrode 205a in the second example implementation may be narrower than the width of the mesa electrode 5a in the first example implementation. The pad electrode 205c may be arranged above the second flat portion F2. As illustrated in FIG. 8, the connection electrode 205b is arranged continuous with the mesa electrode 205a from the top of the second buried layer 217b to the top of the third buried layer 217c, and is connected to the pad electrode 205c. The modulator electrode 205 may be a metal layer, and may be a single layer or a plurality of layers.

The semiconductor laser portion 220 may include a laser electrode 203. As illustrated in FIG. 9, the laser electrode 203 is widely arranged on the upper surface of the mesa structure 9, the upper surface of the second buried layer 217b, and the third buried layer 217c. The laser electrode 203 and the modulator electrode 205 may be layers formed of the same metal, or may be layers formed of layers different from each other.

Also in the second example implementation, the second buried layer 217b is arranged, and hence the step difference amount between the upper surface of the mesa structure 9 and the surface of the buried layer 217 can be stably controlled. Moreover, the second buried layer 217b may be widely exposed, and hence the width of the mesa electrode 205a of the modulator portion 240 in the width direction D2 may be narrowed. The width of the mesa electrode 205a may be proportional to a parasitic capacitance to be caused by the mesa electrode 205a, and hence the parasitic capacitance may be more reduced as the width of the mesa electrode 205a becomes narrower. In this case, the parasitic capacitance to be caused by the mesa electrode 205a does not change even when the third buried layer 217c is completely removed. However, the third buried layer 217c contributes to reduction in parasitic capacitance of the pad electrode 205c. The pad electrode 205c may be required to have a wide area for electrical connection to the outside. Accordingly, the parasitic capacitance of the pad electrode 205c tends to be large. However, the third buried layer 217c may be left below the pad electrode 205c. The parasitic capacitance to be caused by the pad electrode 205c may be inversely proportional to the thickness between the pad electrode 205c and the first conductivity type substrate 1. In this case, the buried layer 217 is a semi-insulating semiconductor layer, and hence the parasitic capacitance becomes smaller as the buried layer 217 becomes thicker in the height direction D3. In the second example implementation, the third buried layer 217c is arranged below the pad electrode 205c, and thus the thickness of the buried layer 217 in the height direction D3 can be increased. Accordingly, the parasitic capacitance to be caused by the pad electrode 205c can be reduced.

It is conceivable to narrow the width of the mesa electrode 5a in the width direction D2 in the first example implementation, but, in this case, the mesa electrode 5a is formed only up to the middle of the third inclined portion C. Stopping the formation of the electrode in the middle of the third inclined portion C may not be preferred from the viewpoint of controllability. In particular, formation of the end portion of the electrode on a surface inclined upward in FIG. 2 (so as to separate from the substrate 1) may cause occurrence of variations. Accordingly, in the first example implementation, the end portion of the mesa electrode 5a in the width direction D2 may be arranged above the upper surface of the second flat portion F2. Meanwhile, in the buried type optical semiconductor device of the second example implementation, substantially flat surfaces may be formed to both sides from the upper surface of the mesa structure 9 without forming (removing) the inclined portion in the buried layer 217. Thus, the end portion of the mesa electrode 5a is not arranged on the inclined surface, with the result that the mesa electrode 205a can be formed to have a width narrower than that in the first example implementation. This configuration can be achieved by arranging the second buried layer 217b at a position at a height close to the upper surface of the mesa structure 9. The second buried layer 217b may be inclined as well, but, as long as the second buried layer 217b is inclined so as to approach the substrate 1, an electrode can be stably formed on the upper surface of the second buried layer 217b. However, it may not be preferred to excessively reduce the inclination angle R of the second buried layer 217b, and the inclination angle R may be desired to fall within the above-mentioned range.

The third buried layer 217c here includes no third inclined portion and no first flat portion, but is not limited thereto. As long as an area that allows the mesa electrode 205a to be arranged on the second buried layer 217b can be ensured, similarly to the first example implementation, the third buried layer 217c may include the third inclined portion and the first flat portion.

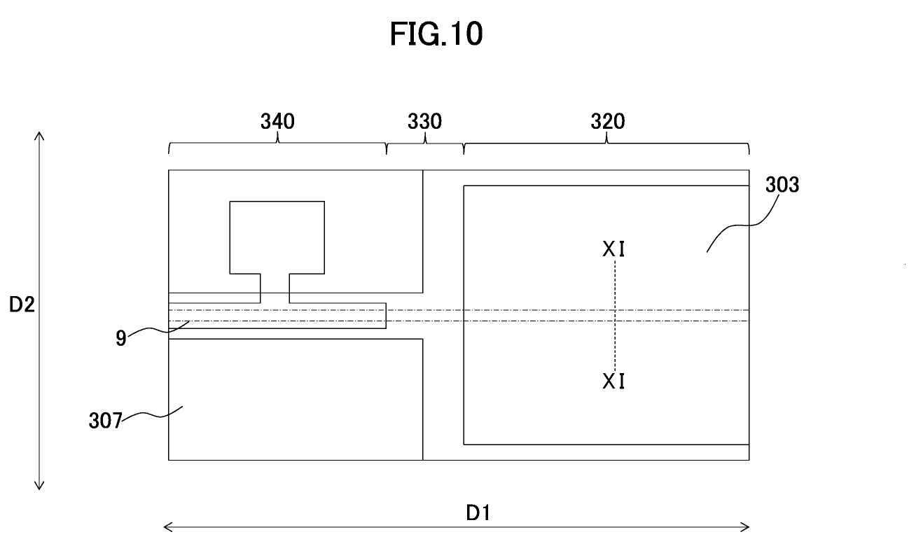

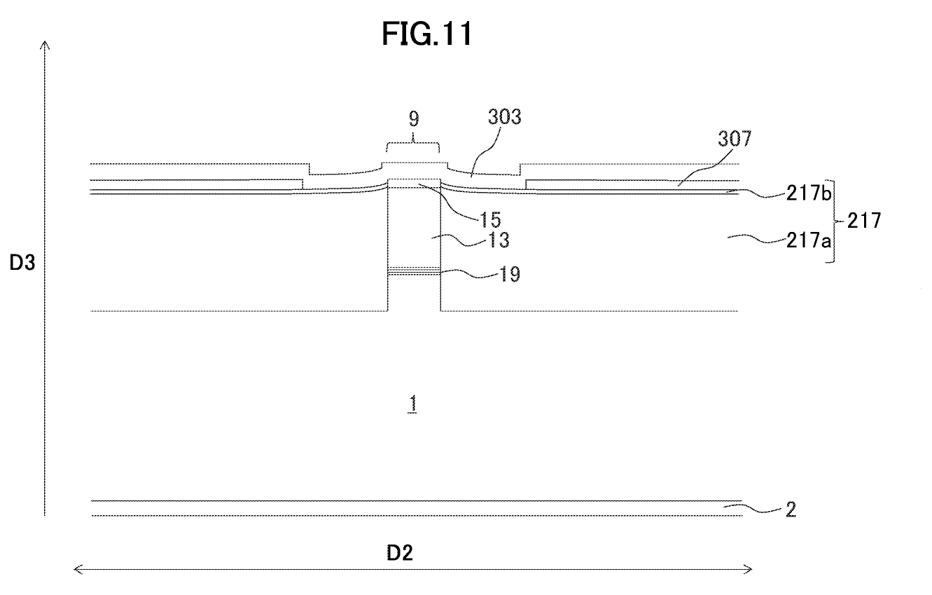

FIG. 10 is a top view of a buried type optical semiconductor device according to a third example implementation of the present invention. FIG. 11 is a schematic sectional view taken along the line XI-XI of FIG. 10. The buried type optical semiconductor device according to the third example implementation includes three optical function devices integrated on the substrate 1. The three optical function devices are a semiconductor laser portion 320, a connecting waveguide portion 330, and a modulator portion 340. The buried type optical semiconductor device according to the third example implementation has the same structure as that of the buried type optical semiconductor device according to the second example implementation except that the shape of the buried layer 217 in the semiconductor laser portion 320 and the shape of the buried layer 217 in the connecting waveguide portion 330 are different.

As illustrated in FIG. 11, the buried layer 217 in the semiconductor laser portion 320 includes the first buried layer 217a and the second buried layer 217b, but does not include the third buried layer unlike the second example implementation. The uppermost layer of the buried layer 217 is the second buried layer 217b. A laser electrode 303 may be arranged on the second buried layer 217b. An insulating film 307 may be arranged in a part of a portion between the laser electrode 303 and the second buried layer 217b.

The sectional structure of the modulator portion 340 is the same as the structure illustrated in FIG. 7 and FIG. 8. Although the sectional structure of the connecting waveguide portion 330 is not shown, in the connecting waveguide portion 330, the third buried layer 217c is arranged in a partial region.

As described in the second example implementation, the third buried layer 217c is required so as to reduce the parasitic capacitance of the pad electrode 205c of the modulator portion 340. Meanwhile, the semiconductor laser portion 320 is DC-driven, and hence the parasitic capacitance does not become a large problem. Meanwhile, in the optical semiconductor device, the heat dissipation performance is an important performance. When a current is injected to the mesa structure 9, heat is generated mainly in an active layer 19. This heat is transmitted to the laser electrode 303 via the buried layer 217 to be released to the outside. Accordingly, the heat dissipation performance becomes higher as the buried layer 217 becomes thinner. In the third example implementation, no third buried layer is arranged in the semiconductor laser portion 320, and hence the thickness of the buried layer is thinner, and the heat dissipation performance is improved as compared with that of the other example implementations.

Some implementations described herein allow, in a buried type optical semiconductor device in which a buried layer is arranged so as to cover a side surface of a mesa structure, an influence of a stress caused by a metal electrode to be reduced or diffusion of a metal included in an electrode to be reduced. This reduction is achieved by forming the buried layer of a first buried layer, a second buried layer, and a third buried layer which is different in material from the second buried layer, and arranging the second buried layer at a position close to a contact layer which is an uppermost layer of the mesa structure. The electrode is arranged in contact with the contact layer and with the second buried layer in the vicinity of the mesa structure. In a width direction of the mesa structure, a distal end of the second buried layer on the mesa structure side is arranged at a position at which an interval between the distal end and the side surface of the mesa structure is 0.5 μm or less. The distal end of the second buried layer may be in contact with the mesa structure. At the distal end, an upper surface of the second buried layer may be arranged to be higher than an upper surface of the contact layer. Further, at the distal end, a lower surface of the second buried layer is arranged to be lower than the upper surface of the contact layer. It may be preferred that, at the distal end, the upper surface of the second buried layer be arranged to be higher than a lower surface of the contact layer. It may be more preferred that, at the distal end, the upper surface of the second buried layer be arranged to be equal to or lower than the upper surface of the contact layer. It may be further more preferred that, at the distal end, the upper surface of the second buried layer be arranged at the same position as the upper surface of the contact layer. The second buried layer includes an inclined portion which is inclined so as to approach a semiconductor substrate as the inclined portion separates from the mesa structure in the width direction. It may be preferred that an angle formed between the inclined portion and the side surface of the mesa structure be 30 degrees or more.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature’s relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A buried type optical semiconductor device, comprising:
a semiconductor substrate;
a mesa structure provided on the semiconductor substrate, the mesa structure including a contact layer and extending in an extending direction;
a buried layer provided so as to cover a side surface of the mesa structure; and
an electrode configured to supply a current to the mesa structure,
wherein the buried layer includes, from the semiconductor substrate side, a first buried layer, a second buried layer, and a third buried layer in the stated order, the third buried layer being formed of a material different from a material of the second buried layer,
wherein the second buried layer has a distal end on the mesa structure side,
wherein, at the distal end, a lower surface of the second buried layer is arranged on the semiconductor substrate side with respect to an upper surface of the contact layer, and
wherein the electrode is in contact with the contact layer and the second buried layer.

2. The buried type optical semiconductor device according to claim 1, wherein the third buried layer is arranged so as to be spaced apart from the mesa structure in a width direction of the mesa structure.

3. The buried type optical semiconductor device according to claim 2, wherein, in the width direction of the mesa structure, an interval between the distal end of the second buried layer and the side surface of the mesa structure is 0.5 μm or less.

4. The buried type optical semiconductor device according to claim 1, wherein the distal end of the second buried layer is in contact with the mesa structure.

5. The buried type optical semiconductor device according to claim 1, wherein, at the distal end, an upper surface of the second buried layer is arranged to be higher than a lower surface of the contact layer.

6. The buried type optical semiconductor device according to claim 5, wherein, at the distal end, the upper surface of the second buried layer is arranged to be equal to or lower than the upper surface of the contact layer.

7. The buried type optical semiconductor device according to claim 6, wherein, at the distal end, the upper surface of the second buried layer is arranged at the same position as the upper surface of the contact layer.

8. The buried type optical semiconductor device according to claim 5, wherein, at the distal end, the upper surface of the second buried layer is arranged to be higher than the upper surface of the contact layer.

9. The buried type optical semiconductor device according to claim 1, wherein the second buried layer has a thickness that is equal to or smaller than a thickness of the contact layer.

10. The buried type optical semiconductor device according to claim 1, wherein the second buried layer has a thickness of 5 nm or more.

11. The buried type optical semiconductor device according to claim 1, wherein the second buried layer includes an inclined portion which is inclined so as to approach the semiconductor substrate as the inclined portion separates from the mesa structure in a width direction of the mesa structure.

12. The buried type optical semiconductor device according to claim 11, wherein an angle formed between the inclined portion of the second buried layer and the side surface of the mesa structure is 30 degrees or more.

13. The buried type optical semiconductor device according to claim 11, wherein an angle formed between the inclined portion of the second buried layer and the side surface of the mesa structure is 60 degrees or more.

14. The buried type optical semiconductor device according to claim 1, wherein the electrode includes a mesa electrode arranged on the mesa structure, a pad electrode arranged above the third buried layer, and a connection electrode arranged between the mesa electrode and the pad electrode.

15. The buried type optical semiconductor device according to claim 14, wherein an end portion of the mesa electrode in a width direction of the mesa structure is arranged above the third buried layer.

16. The buried type optical semiconductor device according to claim 14, wherein an end portion of the mesa electrode in a width direction of the mesa structure is arranged above the second buried layer.

17. The buried type optical semiconductor device according to claim 1, further comprising a semiconductor laser portion and a modulator portion,
wherein the mesa structure is arranged across the semiconductor laser portion and the modulator portion in the extending direction.

18. The buried type optical semiconductor device according to claim 17,
wherein the third buried layer is arranged in the modulator portion, and
wherein the third buried layer is prevented from being arranged in the semiconductor laser portion.

19. The buried type optical semiconductor device according to claim 1,
wherein the third buried layer is formed of semi-insulating InP, and
wherein the second buried layer is a layer formed of a combination of one or more selected from the group consisting of InGaAs, InAlAs, InGaAlAs, InGaAsP, or InAlAsP.

20. The buried type optical semiconductor device according to claim 19,
wherein the first buried layer is formed of semi-insulating InP, and
wherein the semiconductor substrate is formed of InP.
